(19) United States
(12) Patent Application Publication
(10) Pub. No.: US 2019/0279887 A1
(43) Pub. Date: Sep. 12, 2019

(54) VAPOR REDUCTION DEVICE FOR A SEMICONDUCTOR WAFER

(71) Applicants: Kuo Yang Ma, Taipei City (TW); Zhi Kai Huang, Taipei City (TW); Mu-Chun Ho, Taipei City (TW); Wei Chuan Chou, Taipei City (TW); Chun-Fu Wang, Taipei City (TW); Yi-Hsiang Chen, Taipei City (TW); Ying Hsien Cheng, Taipei City (TW)

(72) Inventors: Kuo Yang Ma, Taipei City (TW); Zhi Kai Huang, Taipei City (TW); Mu-Chun Ho, Taipei City (TW); Wei Chuan Chou, Taipei City (TW); Chun-Fu Wang, Taipei City (TW); Yi-Hsiang Chen, Taipei City (TW); Ying Hsien Cheng, Taipei City (TW)

(21) Appl. No.: 15/915,037

(22) Filed: Mar. 7, 2018

(51) Int. Cl. H01L 21/67; H01L 21/673

(52) U.S. Cl. CPC H01L 21/67109; H01L 21/67326

(57) ABSTRACT

A vapor reduction device for a semiconductor wafer has a plurality of heat plates which are spaced arranged longitudinally for receiving a plurality of wafers, the heat plates are integrated into a heating frame which is further placed into a casing. The movements of the heat plates within the casing causes that the wafers can be heated rapidly and uniformly so as to evaporated vapor effectively. The heat plates are separable from the heating frame and thus a number of the heat plates is selectable as desired. The heating temperature for the heat plates is controllable independently so that the temperatures of the wafers are controllable so that the temperature differences of the wafers are controllable to be uniformly distributed.

### FIELD OF THE INVENTION

The present invention is related to semiconductor manufacturing process, and in particular to a vapor reduction device for a semiconductor wafer.

### BACKGROUND OF THE INVENTION

In semiconductor flip chip process, during wafer packaging and fan out packaging, before sputtering metals, the electrodes will have gasification material. Therefore, argon plasma bombarding is used to remove oxides. This process must be down in a very high vacuum, however, in this process, polyimide is used as a protecting layer which encloses the wafer. However, in solidification, vapor within the polyimide will be released in high vacuum environment. This will induce a cleaned wafer to be oxidized again, therefore, before plasma cleaning, the wafer with the polyimide must perform the process of reduction of vapor.

There are some ways for reduction of vapor including the following ways:

Bulb heating, the wafer is heating within a casing with a plurality of bulbs therein. This way has the advantages of quick, high efficiency and low cost, but it is non-uniform heating and uneasy to control so that the temperature difference can not be controlled with 5 degree C.

Furnace heating, in that the wafers are placed within a furnace with a plurality of heaters installed therein. The heating is by radiation, heating speed is low and is non-uniform. Under consideration of a wafer which is heated slower, the baking time is prolonged. As a result, the whole efficiency become low.

Heating plate, each time only one wafer is heated. It has the advantage of well control but the efficiency is very low and thus it can not match the requirement of fan not packaging which need long heating time.

### SUMMARY OF THE INVENTION

To improve the defects in the prior art, the present invention provides a vapor reduction device for a semiconductor wafer, in that the vapor reduction device for a semiconductor wafer has a plurality of heat plates which are spaced arranged longitudinally for receiving a plurality of wafers, the heat plates are integrated into a heating frame which is further placed into a casing. The movements of the heat plates within the casing causes that the wafers can be heated rapidly and uniformly so as to evaporated vapor effectively. The heat plates are separable from the heating frame and thus a number of the heat plates is selectable as desired. The heating temperature for the heat plates is controllable independently so that the temperatures of the wafers are controllable so that the temperature differences of the wafers are controllable to be uniformly distributed.

To achieve above objects, the present invention provides a A vapor reduction device for a semiconductor wafer, comprising: a casing having an opening for transfer of wafers; a heater having a heating frame and a plurality of heating plates; the heater being movable upwards and downwards in the casing; the heating plate being spaced arranged; a wafer frame being combined to the heating frame for locating wafers and the wafer frame being movable to a position for locating wafers or a locating for heating; in a locating position, the wafer frame being moved to a position for receiving or taking out of a wafer and in a heating position, the wafer frame being moved to a position on the heating the wafer.

### BRIEF DESCRIPTION OF THE DRAWINGS

FIG. 1 is a schematic view of the present invention.

FIG. 2 is a schematic view showing the heater and the wafer frame according to the present invention.

FIG. 3 is an exploded view of the heater and wafer frame according to the present invention.

FIG. 4 is another exploded view of the heater and wafer frame according to the present invention.

FIG. 5 is a cross sectional schematic view of the present invention.

FIG. 6 is a schematic view showing the operation of the present invention.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

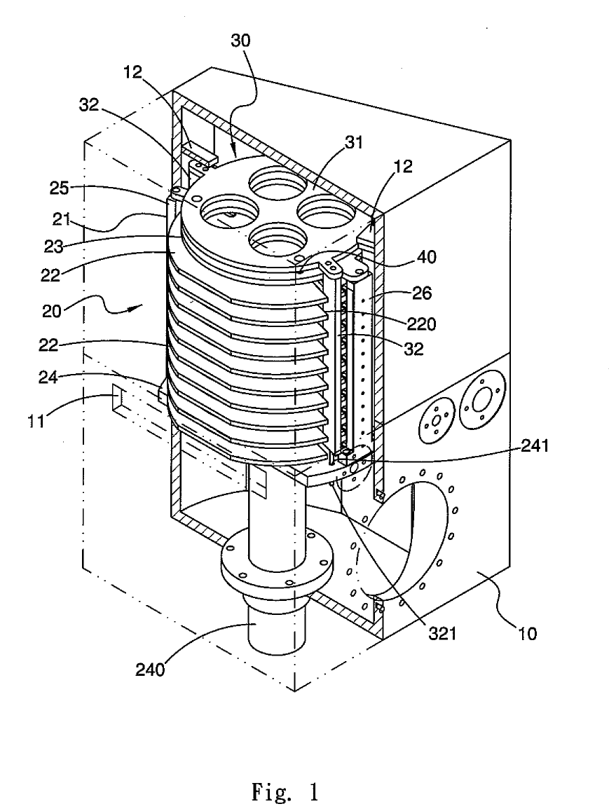

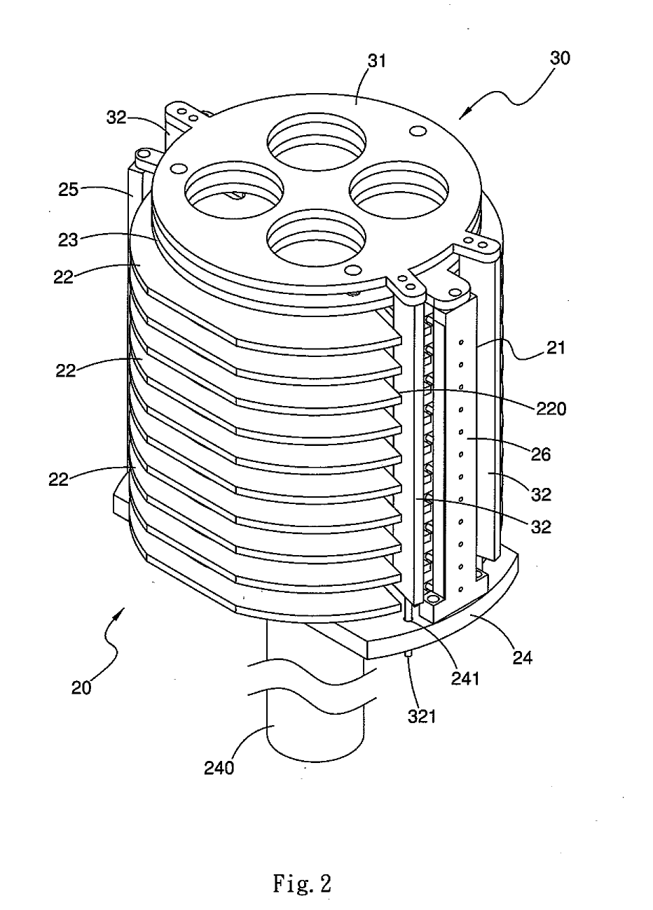

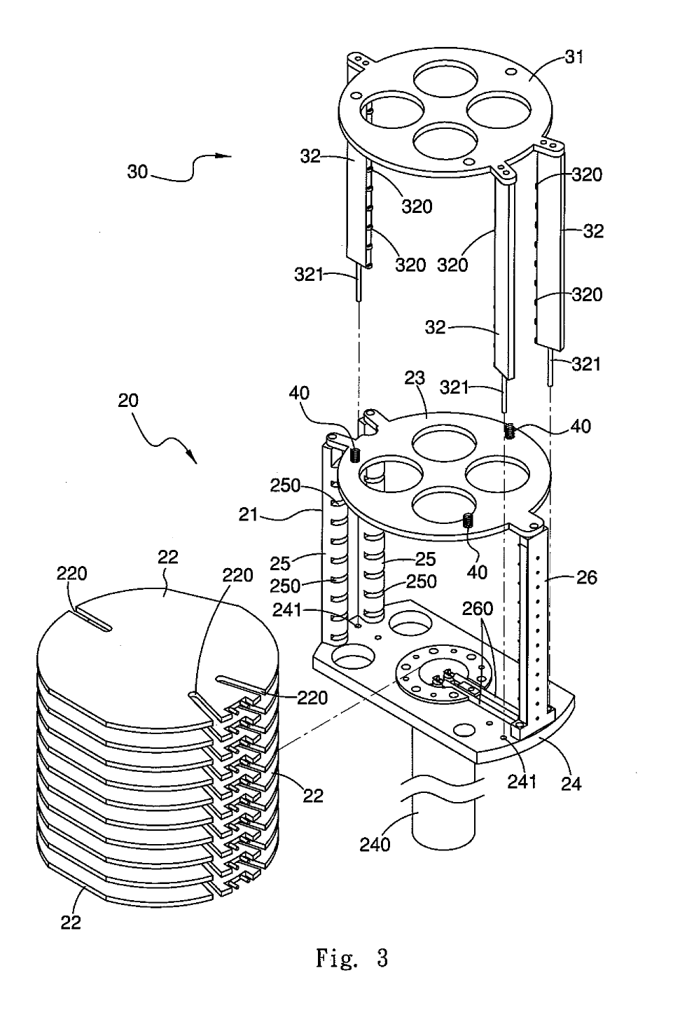

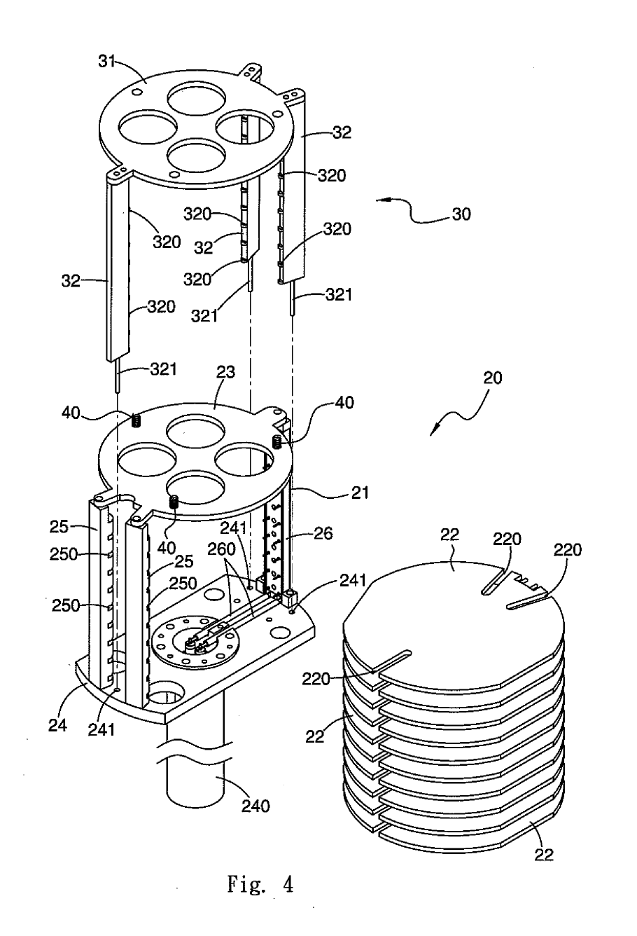

Referring to FIGS. 1 to 6, the structure of the present invention includes:

A casing 10 has an opening 11 for transfer of wafers by using a robot (not shown).

The casing 10 has a cavity and inner upper side of the casing 10 has a plurality of stoppers 20.

A heater 20 has a heating frame 21 and a plurality of heating plates 22. The heater 20 can move up and down in the casing 20. The heating plate 22 are spaced arranged.

The heating frame 21 includes a top plate 23 and a base 24 which is parallel to the top plate 23. Two supporting posts 25 and one heat conductive post 26 are connected between the top plate 23 and the base 24. A bottom of the base 24 is extended with a driving shaft 240. An external driver (not shown) can drive the driving shaft 240 to move up and down within the casing 10. A plurality of guiding holes 241 penetrates through the base 24. Each of the supporting post 25 is formed with a plurality of buckling grooves 250. A heating wire 260 passes through the heat conductive post 26 and extends to the base 24 and then extends downwards to outer side of the casing 10 for input external electric power.

The plurality of heating plates 22 are ceramic plates with heating coils enclosing thereon and one side of each heating plate 22 is embedded into one of the buckling groove 250 and another side thereof is screwedly locked to the heating wire 260 which is electrically connected to a respective one of the heating coils enclosing a respective one of the heating plates 22. Each heating plate 22 has a plurality of notches 220. In this embodiment, the heating wire 260 may includes a plurality of copper rods, two conducive units, two conductive lines etc. These are known in the prior art and thus the details will not be further described herein.

A wafer frame 30 is combined to the heating frame 20 for locating wafers and the wafer frame 30 is moved to a position for locating wafers or a locating for heating. In a locating position, the wafer frame 30 is movable to a position for receiving or taking out of a wafer and in a heating position, the wafer frame is moved to a position on the heating the wafer.

The wafer frame 30 includes an upper plate 31 and a plurality of lateral rods 32 which is connected to the upper plate 31. The upper plate 31 is at an upper side of the top plate 23. The lateral rods 32 are arranged at an outer side of the top plate 23 and is arranged alternatively with the plurality of supporting posts 25 and the heat conductive post 26 and the lateral rods 32 also pass through the notches of the heat plates 22. An inner side of each lateral rod 32 is arranged with a plurality of protrusions 320 at positions with respective to the heat plates 22 for locating wafers 50 by a robot. The wafer 50 can move downwards with the wafer frame 30 to be placed on the top of a respective one of the heat conductive posts 26 for heating.

A plurality of elastomer 40 which may be compressible springs and are located and resist against between the upper plate 31 and the top plate 23. When the heater 20 is driven by the driving shaft 240 to a predetermined position. The upper plate 31 of the wafer frame 30 will resist against the stoppers 12 and thus compress the elastomers 40 to cause the wafer frame 30 to be at a heating position.

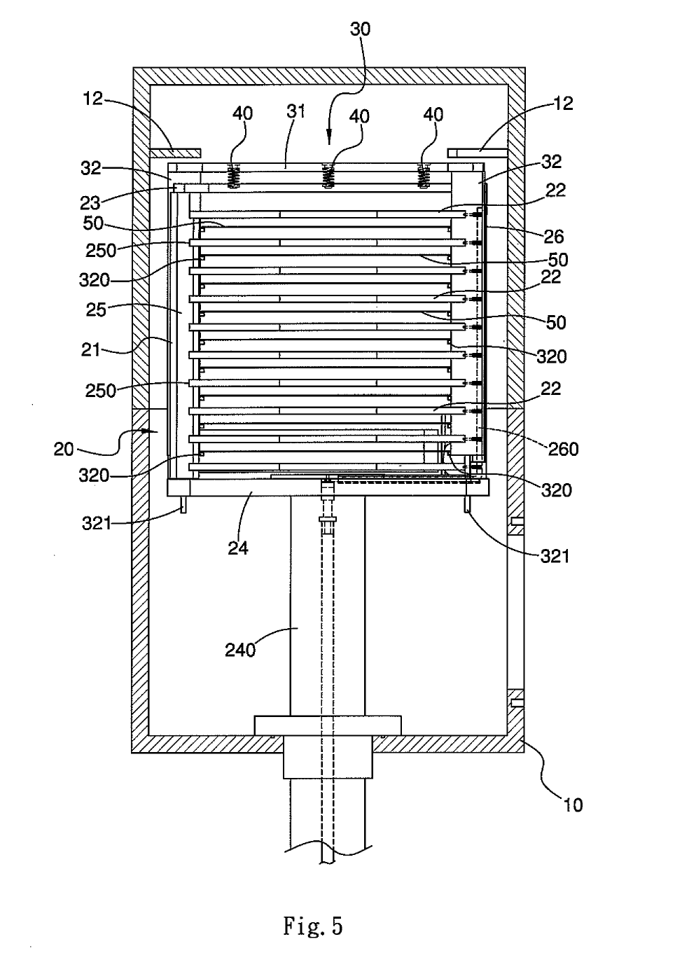

With reference to FIG. 5, it is shown that generally, the wafer frame 30 is at an wafer output position by the elastic force of the elastomers 40. When the driving shaft 240 drives the heater 20 to be moved up and down within the casing 10 so that the robot can transfer the wafers 50 to desire positions.

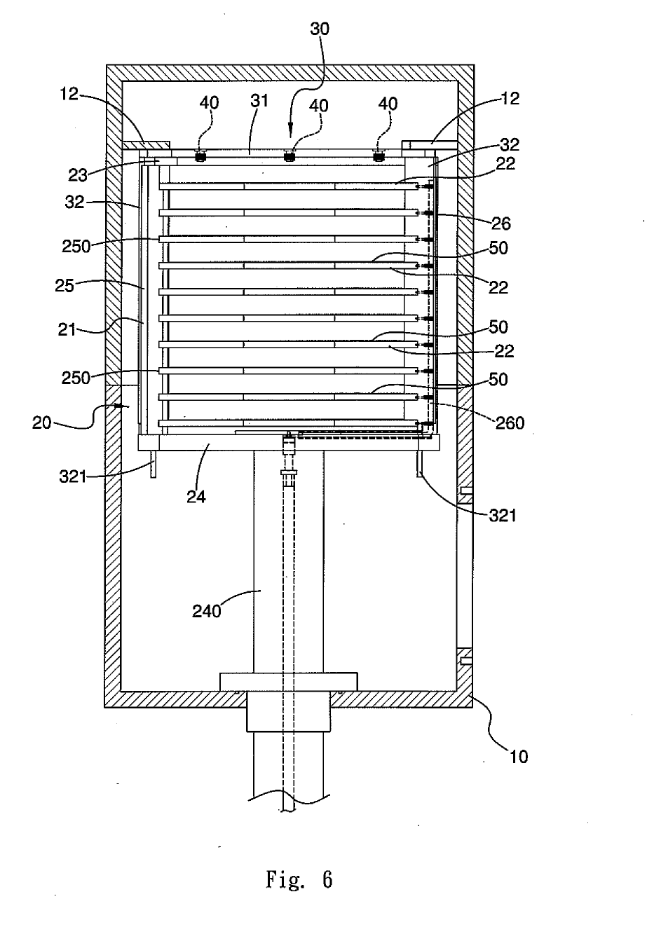

With reference to FIG. 6, when the driving shaft 240 drives the heater 20 upwards to a desired position, the elastomers 40 resists against the upper plate 31 to cause the wafer frame 30 at a heating position. The wafer 50 will move downward with the wafer frame 30 to be at a top surface of a respective one of the heat plates 22 so that the wafer 50 is heated by the heat plates 22 at an upper side and a lower side and thus vapor on the wafer is evaporated. Then the driving shaft 240 move downwards again. By the elastic force of the elastomer 40, the wafer frame 30 will restore to the position for transfer of the wafers, as illustrated in FIG. 5.

The present invention provides a vapor removing device for semiconductor wafers. By a plurality of heat plates 22 which are spaced arranged longitudinally for receiving a plurality of wafers 50, the heat plates 22 are integrated into a heating frame 21 which is further placed into a casing 10. The movements of the heat plates 22 within the casing 10 causes that the wafers 50 can be heated rapidly and uniformly so as to evaporated vapor effectively. The heat plates 22 is separable from the heating frame and thus the number of the heat plates 22 is selectable as desired. The heating temperature for the heat plates 22 is controllable independently so that the temperatures of the wafers are controllable so that the temperature differences of the wafers are controllable to be within 2 degree C.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A vapor reduction device for a semiconductor wafer, comprising:
a casing having an opening for transfer of wafers;
a heater having a heating frame and a plurality of heating plates; the heater being movable upwards and downwards in the casing; the heating plate being spaced arranged;
a wafer frame being combined to the heating frame for locating wafers and the wafer frame being movable to a position for locating wafers or a locating for heating; in a locating position, the wafer frame being moved to a position for receiving or taking out of a wafer and in a heating position, the wafer frame being moved to a position on the heating the wafer.

2. The vapor reduction device for a semiconductor wafer as claimed in claim 1, wherein the casing has a cavity and inner upper side of the casing has a plurality of stoppers; the heating frame includes a top plate and a base which is parallel to the top plate; two supporting posts and one heat conductive post are connected between the top plate and the base; a bottom of the base is extended with a driving shaft; a plurality of guiding holes penetrates through the base; each of the supporting post is formed with a plurality of buckling grooves; a heating wire passes through the heat conductive post and extends to the base and then extends downwards to outer side of the casing for input external electric power.

3. The vapor reduction device for a semiconductor wafer as claimed in claim 2, wherein the plurality of heating plates are ceramic plates with heating coils enclosing thereon and one side of each heating plate is embedded into one of the buckling groove and another side thereof is screwedly locked to the heating wire which is electrically connected to a respective one of the heating coils enclosing a respective one of the heating plates; each heating plate has a plurality of notches.

4. The vapor reduction device for a semiconductor wafer as claimed in claim 3, wherein the heating wire includes a plurality of copper rods, two conducive units, and two conductive lines.

5. The vapor reduction device for a semiconductor wafer as claimed in claim 3, wherein the wafer frame includes an upper plate and a plurality of lateral rods which is connected to the upper plate; the upper plate is at an upper side of the top plate; the lateral rods are arranged at an outer side of the top plate and is arranged alternatively with the plurality of supporting posts and the heat conductive post and the lateral rods also pass through the notches of the heat plates; an inner side of each lateral rod is arranged with a plurality of protrusions at positions with respective to the heat plates for locating wafers; the wafer is movable downwards with the wafer frame to be placed on the top of a respective one of the heat conductive posts for heating.

6. The vapor reduction device for a semiconductor wafer as claimed in claim 5, wherein a plurality of elastomer are located and resist against between the upper plate and the top plate; when the heater is driven by the driving shaft to a predetermined position; the upper plate of the wafer frame will resist against the stoppers and thus compress the elastomers to cause the wafer frame to be at a heating position.

7. The vapor reduction device for a semiconductor wafer as claimed in claim 6, wherein the plurality of elastomer are compressible springs.
